(19) United States
(12) Patent Application Publication
(10) Pub. No.: US 2026/0068725 A1
(43) Pub. Date: Mar. 5, 2026

(54) ELECTRONIC DEVICE

(71) Applicant: InnoLux Corporation, Miao-Li County (TW)

(72) Inventors: Po-Yang HUNG, Miao-Li County (TW); Chin-Lung TING, Miao-Li County (TW); Lung-Shu HUANG, Miao-Li County (TW); Wei-Yuan CHENG, Miao-Li County (TW)

(73) Assignee: InnoLux Corporation, Miao-Li County (TW)

(21) Appl. No.: 19/289,139

(22) Filed: Aug. 4, 2025

Related U.S. Application Data
(60) Provisional application No. 63/690,311, filed on Sep. 4, 2024.

(30) Foreign Application Priority Data
Mar. 28, 2025 (CN) 202510378923.9

(51) Int. Cl. H01L 23/498; H01L 23/00

(52) U.S. Cl. CPC H01L 23/49822

(57) ABSTRACT

An electronic device includes a first electronic unit, a molding layer and a circuit structure. The molding layer surrounds the first electronic unit. The circuit structure is disposed at a side of the molding layer and electrically connected to the first electronic unit. The circuit structure includes a first portion and a second portion disposed between the first portion and the first electronic unit in a normal direction of the electronic device. The first portion includes a first insulating layer, the second portion includes a second insulating layer and a third insulating layer, the second insulating layer is disposed between the first insulating layer and the third insulating layer, the third insulating layer is disposed between the second insulating layer and the molding layer, and a dielectric loss of the second insulating layer is less than dielectric losses of the first insulating layer and the third insulating layer.

### CROSS REFERENCE TO RELATED APPLICATION

This application claims the benefit of U.S. Provisional Application No. 63/690,311, filed on Sep. 4, 2024. The content of the application is incorporated herein by reference.

### BACKGROUND OF THE DISCLOSURE

### 1. Field of the Disclosure

The present disclosure relates to an electronic device, and more particularly to an electronic device having a redistribution layer.

### 2. Description of the Prior Art

In current electronic devices, when high-speed/high-frequency transmission of signals of electronic units is performed through a circuit structure, the wiring (or conductive layer) at the high-speed/high-frequency interface in the circuit structure may have conductor loss due to the skin effect at high frequencies, thereby affecting the electrical performance of the electronic device. Therefore, to improve the circuit structure to achieve high-speed/high-frequency transmission of signals is still an important issue in the present field.

### SUMMARY OF THE DISCLOSURE

The present disclosure aims at providing an electronic device, wherein the circuit structure of the electronic device may be designed to improve electrical performance of the electronic device under high-speed/high-frequency transmission of signals.

An electronic device is provided by the present disclosure, wherein the electronic device includes at least one first electronic unit, a molding layer and a circuit structure. The molding layer surrounds the first electronic unit. The circuit structure is disposed at a side of the molding layer and electrically connected to the first electronic unit. The circuit structure includes a first portion and a second portion, and the second portion is disposed between the first portion and the first electronic unit in a normal direction of the electronic device. The first portion includes a first insulating layer, the second portion includes a second insulating layer and a third insulating layer, the second insulating layer is disposed between the first insulating layer and the third insulating layer, the third insulating layer is disposed between the second insulating layer and the molding layer, and a dielectric loss of the second insulating layer is less than a dielectric loss of the first insulating layer and a dielectric loss of the third insulating layer.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a cross-sectional view of an electronic device according to a first embodiment of the present disclosure.

FIG. 2 schematically illustrates a cross-sectional view of a circuit structure of the electronic device according to the first embodiment of the present disclosure.

FIG. 3 schematically illustrates a cross-sectional view of a circuit structure according to a second embodiment of the present disclosure.

FIG. 4 schematically illustrates a cross-sectional view of a circuit structure according to a third embodiment of the present disclosure.

FIG. 5 schematically illustrates a cross-sectional view of a circuit structure according to a fourth embodiment of the present disclosure.

FIG. 6 schematically illustrates a circuit structure according to a fifth embodiment of the present disclosure.

FIG. 7 schematically illustrates a cross-sectional view of a circuit structure according to a sixth embodiment of the present disclosure.

FIG. 8 schematically illustrates a cross-sectional view of a circuit structure according to a seventh embodiment of the present disclosure.

FIG. 9 schematically illustrates a cross-sectional view of an electronic device according to an eighth embodiment of the present disclosure.

FIG. 10 schematically illustrates a cross-sectional view of an electronic device according to a ninth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that in the present disclosure, when an element is referred to as being “disposed on” another element, the steps or order of the manufacturing process of the element and the another element are not limited. Or, in the present disclosure, when an element is referred to as being “disposed on” another element, the element may be formed on a sidewall of the another element. When an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

In addition, any two values or directions used for comparison may have certain errors. In addition, the terms “equal to”, “equal”, “the same”, “approximately” or “substantially” are generally interpreted as being within ±10%, ±5%, ±3%, ±2%, ±1%, or ±0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

According to the present disclosure, the depth, thickness, length, width and pore size may be measured through optical microscope, electron microscope (such as scanning electron microscope (SEM)) or other suitable ways, but not limited thereto.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may be applied to a power module, a semiconductor package structure, a display device, a light emitting device, a back-light device, an antenna device, a sensing device or a tiled device, but not limited thereto. The electronic device may be a foldable electronic device, a flexible electronic device or a stretchable electronic device. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The display device may include a non-self-emissive display device or a self-emissive display device. The sensing device may include a biosensor, a touch sensor, a fingerprint sensor, other suitable sensors or combinations of the above-mentioned sensors. The antenna device may for example include a liquid crystal antenna device or a non-liquid crystal antenna device. The tiled device may for example include a tiled display device or a tiled antenna device, but not limited thereto. The outline of the electronic device may be a rectangle, a circle, a polygon, a shape with curved edge or other suitable shapes. The electronic device may include electronic elements, wherein the electronic elements may include semiconductor elements. The semiconductor element may be the electronic element including a semiconductor layer or formed through semiconductor process, but not limited thereto. The electronic element may for example include passive elements or active elements, such as capacitor, resistor, inductor, diode, transistor, integrated circuits, and the like. The diode may include a light emitting diode, a photo diode or a varactor diode. The light emitting diode may for example include an organic light emitting diode (OLED), a mini light emitting diode (mini LED), a micro light emitting diode (micro LED) or a quantum dot light emitting diode (QLED), but not limited thereto. It should be noted that the electronic device may be combinations of the above-mentioned devices, but not limited thereto. The electronic device may include peripheral systems such as driving systems, controlling systems, light source systems to support display devices, antenna devices, wearable devices (such as augmented reality devices or virtual reality devices), vehicle devices (such as windshield of car) or tiled devices. The manufacturing method of the electronic device of the present disclosure may for example be applied to a wafer-level package (WLP) process or a panel-level package (PLP) process, but not limited thereto. The manufacturing method of the electronic device of the present disclosure may include a chip-first process or a chip-last process, but not limited thereto. The electronic device may include high bandwidth memory (HBM) package, system on a chip (SoC), system in a package (SiP), antenna in package (AiP), co-packaged optical (CPO) or combinations of the above-mentioned devices, but not limited thereto.

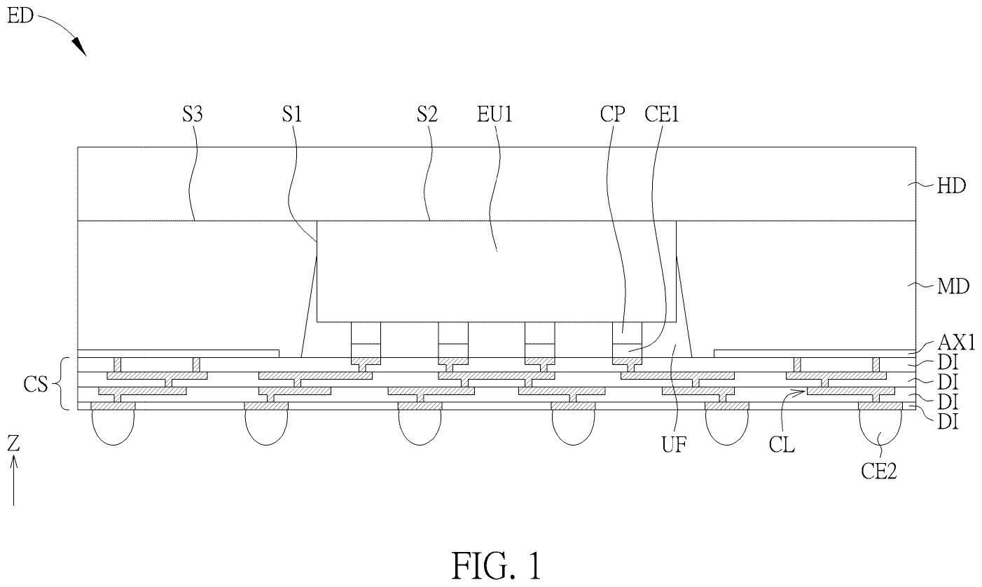

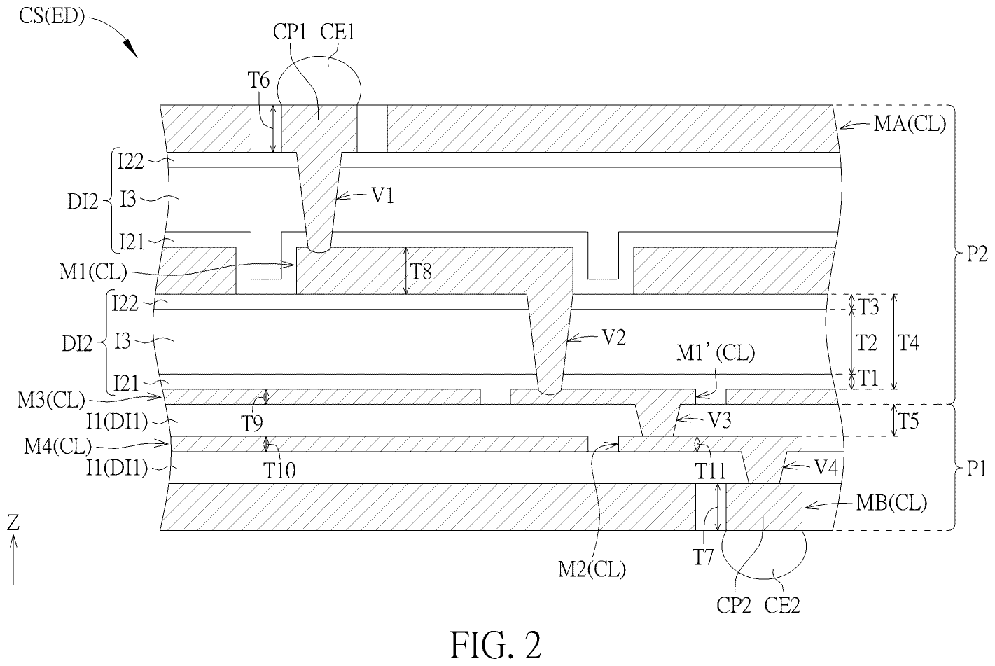

Referring to FIG. 1, FIG. 1 schematically illustrates a cross-sectional view of an electronic device according to a first embodiment of the present disclosure. According to the present embodiment, the electronic device ED may include at least one first electronic unit EU1, a molding layer MD and a circuit structure CS, but not limited thereto. The molding layer MD surrounds the first electronic unit EU1 to reduce the influence of moisture or other external factors on the first electronic unit EU1, but not limited thereto. “An element surrounds another element” described herein may represent that the element contacts at least a portion of the side surface of the another element. For example, as shown in FIG. 1, the molding layer MD may surround at least a portion of the side surface S1 of the first electronic unit EU1. The first electronic unit EU1 may include a semiconductor unit, a memory unit, an antenna unit, a sensing unit, a capacitor or other suitable active electronic units or passive electronic units, depending on the type or purpose of the electronic device ED. The molding layer MD may include any suitable organic material or inorganic material, such as epoxy molding compound (EMC), epoxy resin, oxides or nitrides, but not limited thereto. The circuit structure CS is disposed at a side of the molding layer MD or at a side of the first electronic unit EU1. The circuit structure CS may include a redistribution layer (RDL), but not limited thereto. The redistribution layer may be the layer capable of adjusting the positions of the signal input terminal and the signal output terminal or adjusting the layout of wires. In other words, the circuits may be extended to have a greater spacing through the redistribution layer, or a circuit may be redistributed to another circuit with different spacing. Therefore, the circuit may be redistributed, and/or the fan out area of the circuit may increase. The redistribution layer may include a stacked structure formed by stacking at least one insulating layer and at least one conductive layer, wherein the stacking direction of the insulating layer(s) and the conductive layer(s) may for example parallel to the normal direction (that is, the direction Z, which will not be redundantly described) of the electronic device ED. The circuit structure CS may be electrically connected to the first electronic unit EU1 and may be used to transmit signals of the first electronic unit EU1. Specifically, the circuit structure CS of the present embodiment may include at least one conductive layer CL and at least one dielectric layer DI, or the circuit structure CS may be formed by stacking at least one conductive layer CL and at least one dielectric layer DI, wherein the conductive layer CL in the circuit structure CS may be electrically connected to the first electronic unit EU1. It should be noted that the circuit structure CS shown in FIG. 1 is just exemplary, and the detail of the structure of the circuit structure CS of the present embodiment may refer to FIG. 2 and following contents. In detail, the electronic device ED may further include a first connecting element CE1 disposed between the circuit structure CS and the first electronic unit EU1. Specifically, the first connecting element CE1 may be disposed corresponding to the uppermost conductive layer (that is, the first conductive pad CP1 shown in FIG. 2 and described in the following) of the circuit structure CS, that is, in the normal direction of the electronic device ED, the first connecting element CE1 may overlap or at least partially overlap the first conductive pad CP1. In addition, the first electronic unit EU1 may include at least one conductive pad CP located at a side of the first electronic unit EU1 facing the circuit structure CS, wherein the conductive pad CP may correspond to the first connecting element CE1 and be electrically connected to the first connecting element CE1. Therefore, the circuit structure CS may be electrically connected to the first electronic unit EU1 through the first connecting element CE1, but not limited thereto. The first connecting element CE1 may for example include solder, but not limited thereto. In some embodiments, the circuit structure CS may be electrically connected to the first electronic unit EU1 by hybrid bonding (for example, the conductive layer CL (that is, the first conductive pad CP1) of the circuit structure CS may directly contact the conductive pad CP of the first electronic unit EU1). In such condition, the electronic device ED may not include the first connecting element CE1. It should be noted that although it is not shown in FIG. 1, the circuit structure CS may further include various kinds of wires, circuits or electronic units that can be applied to the electronic device ED and are formed of the conductive layers CL of the circuit structure CS, but not limited thereto. The electronic unit may include any suitable active element and/or passive element.

The electronic device ED of the present embodiment may further include a second connecting element CE2 disposed at a side of the circuit structure CS opposite to the first electronic unit EU1. That is, the first connecting element CE1 and the second connecting element CE2 are respectively disposed at two sides of the circuit structure CS. The second connecting element CE2 may be electrically connected to the circuit structure CS. Specifically, the second connecting element CE2 may be disposed corresponding to the lowermost conductive layer (that is, the second conductive pad CP2 shown in FIG. 2 and described in the following) in the circuit structure CS, that is, the second connecting element CE2 may overlap or at least partially overlap the second conductive pad CP2 in the normal direction of the electronic device ED. In such condition, the electronic device ED may further include an electronic unit (not shown in FIG. 1) disposed at a side of the circuit structure CS opposite to the first electronic unit EU1, wherein the circuit structure CS may be electrically connected to the electronic unit through the second connecting element CE2. Therefore, the first electronic unit EU1 may be electrically connected to the electronic unit through the first connecting element CE1, the circuit structure CS and the second connecting element CE2.

The electronic device ED of the present embodiment may further include an underfill layer UF disposed between the first electronic unit EU1 and the circuit structure CS and surrounds the first connecting element CE1. The underfill layer UF may further surround the first electronic unit EU1 or contact at least a portion of the side surface S1 of the first electronic unit EU1, but not limited thereto. The molding layer MD may surround the first electronic unit EU1 and the underfill layer UF. The underfill layer UF may include any suitable insulating material, such as epoxy resin or acrylic resin, but not limited thereto. The underfill layer UF may for example be used for providing moisture-and-oxygen blocking effect to the first connecting element CE1 and the conductive pad CP.

The electronic device ED of the present embodiment may further include a heat dissipation layer HD disposed at a side of the first electronic unit EU1 (or the molding layer MD). Specifically, the heat dissipation layer HD may be disposed at the side of the first electronic unit EU1 (or the molding layer MD) opposite to the circuit structure CS. The molding layer MD may not cover the surface S2 of the first electronic unit EU1 opposite to the circuit structure CS, for example, the surface S3 of the molding layer MD may be aligned with the surface S2 of the first electronic unit EU1. In such condition, the heat dissipation layer HD may contact at least a portion of the surface S2 of the first electronic unit EU1. For example, the heat dissipation layer HD may contact the surface S2 of the first electronic unit EU1 and the surface S3 of the molding layer MD, but not limited thereto. Therefore, the heat dissipation layer HD may provide a heat dissipation effect to the first electronic unit EU1, thereby improving the reliability of the electronic device ED. In some embodiments, the molding layer MD may cover the surface S2 of the first electronic unit EU1.

The electronic device ED of the present embodiment may further include a first auxiliary layer AX1 disposed between the molding layer MD and the circuit structure CS. Specifically, the first auxiliary layer AX1 may be disposed at a position on the circuit structure CS not corresponding to the first electronic unit EU1 and may be covered by the molding layer MD. The first auxiliary layer AX1 may include metal materials, but not limited thereto. In addition, the thermal conductivity of the material of the first auxiliary layer AX1 may range from 80 W·m⁻¹·K⁻¹ to 440 W·m⁻¹·K⁻¹. For example, in the present embodiment, a metal material having a thermal conductivity within the above-mentioned range may be selected as the material of the first auxiliary layer AX1, but not limited thereto. In some embodiments, the first auxiliary layer AX1 may serve as a heat dissipation layer to provide a heat dissipation effect for the circuit structure CS. In some embodiments, the first auxiliary layer AX1 may serve as a shielding layer of the conductive layers CL in the circuit structure CS. The first auxiliary layer AX1 may be electrically connected to the conductive layers CL in the circuit structure CS, as shown in FIG. 1, but not limited thereto. In some embodiments, the first auxiliary layer AX1 may not be electrically connected to the conductive layers CL in the circuit structure CS.

It should be noted that the structure of the electronic device ED shown in FIG. 1 is exemplary, and the electronic device ED of the present embodiment may further include other suitable elements or layers.

Referring to FIG. 2, FIG. 2 schematically illustrates a cross-sectional view of a circuit structure of the electronic device according to the first embodiment of the present disclosure. According to the present embodiment, the circuit structure CS of the electronic device ED may include at least one first portion P1 and at least one second portion P2, or the circuit structure CS includes a structure formed by stacking at least one first portion P1 and at least one second portion P2, wherein the stacking direction of the first portion(s) P1 and the second portion(s) P2 may be parallel to the normal direction of the electronic device ED. For example, in the present embodiment, as shown in FIG. 2, the circuit structure CS may include a first portion P1 and a second portion P2 or include a structure formed by stacking a first portion P1 and a second portion P2, but not limited thereto. In other embodiments, the circuit structure CS may include a structure formed by stacking a plurality of first portions P1 and a plurality of second portions P2, wherein the stacking order of the plurality of first portions P1 and the plurality of second portions P2 may be determined according to the design of the circuit structure CS. As shown in FIG. 2, in the present embodiment, the second portion P2 may be disposed on the first portion P1. That is, referring to FIG. 1 and FIG. 2, the second portion P2 is disposed between the first portion P1 and the first electronic unit EU1 in the normal direction of the electronic device ED. In other words, in the circuit structure CS, the second portion P2 may be closer to the first electronic unit EU1 than the first portion P1.

The first portion P1 of the circuit structure CS may include a structure formed by stacking at least one conductive layer CL and at least one first dielectric layer DI1. “The first dielectric layer DI1” described herein may represent one of the dielectric layers DI located in the first portion P1 shown in FIG. 1. The second portion P2 of the circuit structure CS may include a structure formed by stacking at least one conductive layer CL and at least one second dielectric layer DI2. “The second dielectric layer DI2” described herein may represent one of the dielectric layers DI located in the second portion P2 shown in FIG. 1. According to the present embodiment, the first dielectric layer DI1 of the first portion P1 of the circuit structure CS may include a first insulating layer I1, and the second dielectric layer DI2 of the second portion P2 of the circuit structure CS may include a third insulating layer I3 and at least one second insulating layer. For example, as shown in FIG. 2, the second dielectric layer DI2 may include a third insulating layer I3, and a second insulating layer I21 and a second insulating layer I22 respectively disposed at two sides of the third insulating layer I3, wherein the third insulating layer I3 may be sandwiched between the second insulating layer I21 and the second insulating layer I22, but not limited thereto. In some embodiments, the second dielectric layer DI2 may include a third insulating layer I3 and a second insulating layer disposed at a side of the third insulating layer I3 (that is, one of the second insulating layer I21 and the second insulating layer I22). In such condition, the first insulating layer I1 may define a first dielectric layer DI1, and the second insulating layer I21, the second insulating layer I22 and the third insulating layer I3 may define a second dielectric layer DI2. That is, the first dielectric layer DI1 may include a single-layer structure, and the second dielectric layer DI2 may include a multi-layer structure, but not limited thereto. In other words, the structures of the dielectric layers in different portions of the circuit structure CS of the electronic device ED may be different. In some embodiments, the second insulating layer I21 and the second insulating layer I22 may for example be disposed at two sides of the third insulating layer I3 by sputtering to form the second dielectric layer DI2, but not limited thereto.

According to the present embodiment, in the circuit structure CS, the dielectric loss (or dissipation factor (Df)) of the second insulating layer (including the second insulating layer I21 and/or the second insulating layer I22) in the second dielectric layer DI2 of the second portion P2 may be less than the dielectric loss of the third insulating layer I3 in the second dielectric layer DI2 of the second portion P2 and the dielectric loss of the first insulating layer I1 in the first dielectric layer DI1 of the first portion P1. The dielectric losses (or dissipation factors (Df)) of the second insulating layer I21 and the second insulating layer I22 may be less than or equal to 0.01. In addition, the dielectric loss of the third insulating layer I3 may be less than the dielectric loss of the first insulating layer I1, but not limited thereto. Specifically, a material having a dielectric loss (or dissipation factor (Df) less than the dielectric loss of the material of the first insulating layer I1 and the dielectric loss of the material of the third insulating layer I3 may be selected as the material of the second insulating layer. In addition, a material having a dielectric loss (or dissipation factor (Df) less than the dielectric loss of the material of the first insulating layer I1 may be selected as the material of the third insulating layer I3. In the present embodiment, the material of the second insulating layer may include silicon nitride (SiNₓ), silicon oxide (SiOₓ), other suitable materials or combinations of the above-mentioned materials, but not limited thereto. The first insulating layer I1 and the third insulating layer 13 may include any suitable insulating material according to the material design mentioned above. For example, in the present embodiment, the first insulating layer I1 may include polyimide (PI) which has dielectric loss (or dissipation factor (Df)) less than or equal to 0.02 in the frequency range from 1 GHz to 100 GHz, and the third insulating layer I3 may include Ajinomoto Build-up Film (ABF) material which has dielectric loss less than or equal to 0.02 in the frequency range from 1 GHz to 100 GHz, but not limited thereto. In such condition, the dielectric loss of the second dielectric layer DI2 in the second portion P2 may be less than the dielectric loss of the first dielectric layer DI1 in the first portion P1. According to some embodiments, the second insulating layer I21 and the second insulating layer I22 may both include silicon oxide (SiOₓ), but the oxygen contents of these two insulating layers may be different. For example, the second insulating layer I21 may include SiO_{1.2}, and the second insulating layer I22 may include SiO_{1.5}, but not limited thereto. In addition to material analysis and comparison, “the dielectric loss” mentioned in the present disclosure may also be measured through a cavity resonator or through ASTM D150 method, but not limited thereto.

Through the structural design mentioned above, the circuit structure CS of the electronic device ED of the present embodiment may be observed to include a first portion P1 and a second portion P2 having dielectric layers of different structures, wherein the first portion P1 may include the first insulating layer I1, the second portion P2 may include the second insulating layer (such as the second insulating layer I21) and the third insulating layer I3, the second insulating layer I21 is disposed between the first insulating layer I1 and the third insulating layer I3, the third insulating layer I3 is disposed between the second insulating layer I21 and the molding layer MD, and the dielectric loss of the second insulating layer I21 is less than the dielectric loss of the first insulating layer I1 and the dielectric loss of the third insulating layer I3.

According to the present embodiment, the second dielectric layer DI2 of the second portion P2 may have a thickness T4, and the first dielectric layer DI1 of the first portion P1 may have a thickness T5, wherein the thickness T5 of the first dielectric layer DI1 may be less than the thickness T4 of the second dielectric layer DI2. When the first portion P1 includes a plurality of first dielectric layers DI1, the thickness T5 may be the thickness of any one of the first dielectric layers DI1 in the first portion P1, and the thicknesses of the plurality of first dielectric layers DI1 may be the same or different. The thickness T5 may be defined as the thickness of the portion of the first dielectric layer DI1 located between two adjacent conductive layers CL, but not limited thereto. In the present embodiment, since the first dielectric layer DI1 is defined by the first insulating layer I1, the thickness T5 may also be regarded as the thickness of the first insulating layer I1. When the second portion P2 includes a plurality of second dielectric layers DI2, the thickness T4 may be the thickness of any one of the second dielectric layers DI2 in the second portion P2, and the thicknesses of the plurality of second dielectric layers DI2 may be the same or different. The thickness T4 may be defined as the thickness of the portion of the second dielectric layer DI2 located between two adjacent conductive layers CL, but not limited thereto. In the present embodiment, since the second dielectric layer DI2 is defined by the second insulating layer I21, the third insulating layer I3 and the second insulating layer I22, the thickness T4 may be the sum of the thickness T1 of the second insulating layer I21, the thickness T2 of the third insulating layer I3 and the thickness T3 of the second insulating layer I22 (that is, T4=T1+T2+T3), but not limited thereto. In some embodiments, when the second dielectric layer DI2 only includes the third insulating layer I3 and a second insulating layer, the thickness T4 may be the sum of the thickness T2 and the thickness T1 (or the thickness T3). In other words, the sum of the thickness T1 of the second insulating layer I21, the thickness T2 of the third insulating layer I3, and the thickness T3 of the second insulating layer I22 may be greater than the thickness (that is, the thickness T5) of the first insulating layer I1. The thickness T1 of the second insulating layer I21 and the thickness T3 of the second insulating layer I22 may be the same or different, it is not limited in the present embodiment. In addition, in the present embodiment, the thickness T2 of the third insulating layer 13 may be greater than the thickness of the second insulating layer, that is, the thickness T2 is greater than the thickness T1 of the second insulating layer I21 and the thickness T3 of the second insulating layer I22. Specifically, a ratio of the thickness T1 of the second insulating layer I21 (or the thickness T3 of the second insulating layer I22) to the thickness T2 of the third insulating layer I3 may be greater than or equal to 0.005 and less than or equal to 0.5 (that is, 0.005≤T1/T2 or T3/T2≤0.5), but not limited thereto. Through the thickness design mentioned above, the risk of signal loss may be reduced. The thickness T5 of the first dielectric layer DI1 (or the first insulating layer I1) may range from 2 micrometers (μm) to 15 μm (that is, 2 μm≤T5≤15 μm). The thickness of the second insulating layer (including the thickness T1 and the thickness T3) may range from 0.01 μm to 5 μm (that is, 0.01 μm≤T1 or T3≤5 μm). The thickness T2 of the third insulating layer I3 may range from 10 μm to 25 μm (that is, 10 μm≤T2≤25 μm). “The thickness of an element” mentioned in the present disclosure may be the maximum thickness, the minimum thickness or the average thickness of the thicknesses measured at at least 5 positions of the element in a cross-sectional view.

In the present embodiment, the coefficient of thermal expansion of the second insulating layer (including the second insulating layer I21 and the second insulating layer I22) may be less than the coefficient of thermal expansion of the third insulating layer I3. The coefficient of thermal expansion of the second insulating layer (including the second insulating layer I21 and the second insulating layer I22) may range from 0.2 ppm·K⁻¹ to 3.5 ppm·K⁻¹. The coefficient of thermal expansion of the third insulating layer 13 may range from 20 ppm·K⁻¹ to 60 ppm·K⁻¹. In addition, the warping tendency of the second insulating layer may be opposite to the warping tendency of the third insulating layer I3. In detail, when the second dielectric layer DI2 is heated, the second insulating layer may be warped upward and the third insulating layer I3 may be warped downward, or the second insulating layer may be warped downward and the third insulating layer I3 may be warped upward. Specifically, in the structural design of the second dielectric layer DI2, materials meeting the above-mentioned conditions may be selected as the material of the second insulating layer and the material of the third insulating layer I3 respectively. Through the above-mentioned design, the possibility of warping of the electronic device ED may be reduced.

According to the present embodiment, the conductive layers CL of the second portion P2 of the circuit structure CS may include a first conductive layer M1, wherein the first conductive layer M1 may be a signal related layer in the second portion P2. In the present disclosure, the “signal related layer” may represent the conductive layer used for transmitting the signal of the first electronic unit EU1 or the conductive layer used for forming the signal transmission path of the first electronic unit EU1. In such condition, the first conductive layer M1 may be electrically connected to the first electronic unit EU1. Specifically, the circuit structure CS may include an uppermost conductive layer MA and a lowermost conductive layer MB, wherein the conductive layer MA and the conductive layer MB may be under bump metallization (UBM), but not limited thereto. The conductive layer MA may form the first conductive pad CP1 mentioned above, and the conductive layer MB may form the second conductive pad CP2 mentioned above. That is, the first conductive pad CP1 and the second conductive pad CP2 are disposed at two sides of the circuit structure CS respectively, and the first conductive pad CP1 may be disposed between the second conductive pad CP2 and the first electronic unit EU1. In the present embodiment, since the circuit structure CS includes a structure formed by stacking a first portion P1 and a second portion P2, the conductive layer MA may be the uppermost conductive layer among the conductive layers CL in the second portion P2, and the conductive layer MB may be the lowermost conductive layer among the conductive layers CL in the first portion P1, but not limited thereto. In other embodiments, when the circuit structure CS includes a structure formed by stacking a plurality of first portions P1 and a plurality of second portions P2, the conductive layer MA may be the uppermost conductive layer among the conductive layers CL in the uppermost first portion P1 or the uppermost second portion P2, and the conductive layer MB may be the lowermost conductive layer among the conductive layers CL in the lowermost first portion P1 or the lowermost second portion P2. The first conductive pad CP1 may be electrically connected to the first conductive layer M1. For example, as shown in FIG. 2, the first conductive pad CP1 may be electrically connected to the first conductive layer M1 through a via V1 penetrating the second dielectric layer DI2. In addition, the first conductive pad CP1 may further be electrically connected to the first connecting element CE1, and the details thereof may refer to the contents mentioned above and will not be redundantly described. Therefore, the first conductive layer M1 may be electrically connected to the first electronic unit EU1 through the first conductive pad CP1 and the first connecting element CE1. As shown in FIG. 2, the conductive layers CL in the second portion P2 may further include another signal related layer (that is, the first conductive layer M1′), and the first conductive layer M1 and the first conductive layer M1′ may be electrically connected to each other through a via V2 penetrating the second dielectric layer DI2. The via V1 and the via V2 may be formed by removing portions of the second insulating layer I21, the third insulating layer I3 and the second insulating layer I22, but not limited thereto. In the present embodiment, in the second dielectric layer DI2, the second insulating layer I22 located on the third insulating layer I3 may not fill the via (such as the via V1 and the via V2) in the second portion P2, or the second insulating layer I22 is not disposed along the sidewall of the via, but not limited thereto. In some embodiments, as shown in FIG. 2, the conductive layers CL (such as the first conductive layer M1 and the first conductive layer M1′) in the second portion P2 may respectively include a recess portion at a position in contact with the via (including the via V1 and the via V2). For example, in the process of forming the via, a portion of the top surface of the conductive layer CL corresponding to the via may further be removed to form the recess portion, but not limited thereto. It should be noted that although it is not shown in following figures, the conductive layers in the second portion P2 may include or not include the recess portion. According to some embodiments, when the conductive layer CL includes the recess portion, a ratio of the depth of the recess portion to the thickness of the conductive layer CL may be greater than or equal to 0.05 and less than or equal to 0.5, or greater than or equal to 0.1 and less than or equal to 0.3 along the normal direction of the electronic device ED. Through the above-mentioned design, the influence on impedance may be reduced, but not limited thereto.

According to the present embodiment, the conductive layers CL in the first portion P1 of the circuit structure CS may include a second conductive layer M2, wherein the second conductive layer M2 may be the signal related layer in the first portion P1. The signal related layer (such as the first conductive layer M1 and the first conductive layer M1′) in the second portion P2 may be electrically connected to the signal related layer (such as the second conductive layer M2) in the first portion P1. In detail, the first conductive layer M1′ in the second portion P2 may be electrically connected to the second conductive layer M2 in the first portion P1 through a via V3 penetrating the first dielectric layer DI1 (such as the first dielectric layer DI1 adjacent to the second portion P2). The second conductive layer M2 may be electrically connected to the second conductive pad CP2. For example, as shown in FIG. 2, the second conductive layer M2 may be electrically connected to the second conductive pad CP2 through a via V4 penetrating the first dielectric layer DI1. The via V3 and the via V4 may be formed by removing a portion of the first insulating layer I1, but not limited thereto. As mentioned above, the second conductive pad CP2 may be electrically connected to the second connecting element CE2, and the second connecting element CE2 may be electrically connected to an electronic unit (not shown). Therefore, in the circuit structure CS, a signal transmission path between the first electronic unit EU1 and another electronic unit may be formed through the first conductive pad CP1, the signal related layer in the second portion P2 (such as the first conductive layer M1 and the first conductive layer M1′), the signal related layer in the first portion P1 (such as the second conductive layer M2) and the second conductive pad CP2. It should be noted that FIG. 2 just exemplary shows a signal transmission path in the circuit structure CS, and the circuit structure CS may include other signal transmission paths. That is, the second portion P2 may include other signal related layers electrically connected to other first conductive pads CP1 and other first connecting elements CE1; the first portion P1 may include other signal related layers electrically connected to other second conductive pads CP2 and other second connecting elements CE2.

In the present embodiment, the first conductive pad CP1 may have a thickness T6, and the second conductive pad CP2 may have a thickness T7, wherein the thickness T7 may be greater than the thickness T6. In addition, the thickness T6 of the first conductive pad CP1 and the thickness T7 of the second conductive pad CP2 may both be greater than or equal to 7 μm (that is, T6,T7≥7 μm), but not limited thereto. Moreover, in the present embodiment, the elastic coefficient of the first connecting element CE1 may be different from the elastic coefficient of the second connecting element CE2. Specifically, two conductive materials with different elastic coefficients may be selected as the materials of the first connecting element CE1 and the second connecting element CE2 respectively.

According to the present embodiment, in addition to the signal related layer, the conductive layers CL in the second portion P2 of the circuit structure CS may further include at least one shielding layer adjacent to a signal related layer located in the second portion P2 and at least partially overlapped with the signal related layer. For example, as shown in FIG. 2, the conductive layers CL of the second portion P2 may further include a third conductive layer M3, wherein the third conductive layer M3 may be adjacent to the first conductive layer M1 and may correspond to the first conductive layer M1. Specifically, in the normal direction of the electronic device ED, the third conductive layer M3 may at least partially overlap the first conductive layer M1. In such condition, the third conductive layer M3 may serve as the shielding layer of the first conductive layer M1. “The third conductive layer M3 is adjacent to the first conductive layer M1” mentioned above may represent that no other conductive layer CL is included between the third conductive layer M3 and the first conductive layer M1 in the normal direction of the electronic device ED. In the present embodiment, in the second portion P2, shielding layers may be located above and below a signal related layer, wherein the shielding layers at least partially overlap the signal related layer and are adjacent to the signal related layer, but not limited thereto. For example, as shown in FIG. 2, for the first conductive layer M1, there may be a conductive layer MA above the first conductive layer M1, wherein the conductive layer MA is adjacent to and at least partially overlapped with the first conductive layer M1; and there may be a third conductive layer M3 below the first conductive layer M1, wherein the third conductive layer M3 is adjacent to and at least partially overlapped with the first conductive layer M1. In such condition, the conductive layer MA may be regarded as the shielding layer of the first conductive layer M1. It should be noted that although FIG. 2 shows a structure in which the conductive layer MA may be used as the shielding layer, it is not limited in the present disclosure. In other embodiments, the conductive layer MA may not be adjacent to the first conductive layer M1 and may not serve as the shielding layer. In some embodiments, in the second portion P2, the shielding layer may only exist above or below a signal related layer. In the present embodiment, the following test may for example be used to determine whether a conductive layer CL in the second portion P2 is a signal related layer or a shielding layer. In detail, although it is not shown in the figure, each conductive layer CL in the second portion P2 may be electrically connected to a connecting element through a via in the second dielectric layer DI2. In such condition, a connecting element to which a conductive layer CL is electrically connected may be electrically connected to a conductive pad, wherein the conductive pad may for example be grounded. If there is a voltage difference between the connecting element and the conductive pad, the conductive layer CL may be determined to be a signal related layer (such as the first conductive layer M1); if there is a short circuit between the connecting element and the conductive pad, the conductive layer CL may be determined to be a shielding layer (such as the third conductive layer M3). Although it is not clearly shown, the conductive layer CL in the first portion P1 of the circuit structure CS may also include a shielding layer adjacent to the signal related layer (that is, the second conductive layer M2) and at least partially overlapped with the signal related layer.

According to the present embodiment, the conductive layers CL in the first portion P1 of the circuit structure CS may further include a fourth metal layer M4, wherein the fourth metal layer M4 may be a non-signal related layer. In the present disclosure, “the non-signal related layer” may refer to a conductive layer CL which is not used to transmit signals of the first electronic unit EU1, but not limited thereto. The shielding layer mentioned above may also be regarded as the non-signal related layer. In the present embodiment, the fourth metal layer M4 may for example include a ground layer, a power layer or other suitable layers. It should be noted that although it is not clearly shown, the conductive layers CL in the second portion P2 may also include non-signal related layers such as the ground layer, the power layer and the like.

According to the present embodiment, the thickness of the signal related layer in the second portion P2 may be greater than or equal to 3 μm, but not limited thereto. It should be noted that “the thickness of the signal related layer in the second portion P2 is greater than or equal to 3 μm” described herein may include the condition that the thickness of at least one signal related layer in the second portion P2 is greater than or equal to 3 μm. For example, as shown in FIG. 2, the first conductive layer M1 in the second portion P2 may have a thickness T8, wherein the thickness T8 may be greater than or equal to 3 μm (that is, T8≥3 μm). In other words, in the second portion P2, it can be observed that the thickness of at least one of the conductive layers CL electrically connected to the first electronic unit EU1 is greater than or equal to 3 μm. In some embodiments, the thicknesses of all signal related layers in the second portion P2 may be greater than or equal to 3 μm.

According to the present embodiment, in the second portion P2, the thickness of the shielding layer may be less than the thickness of the signal related layer. For example, as shown in FIG. 2, the third conductive layer M3 in the second portion P2 may have a thickness T9, and the thickness T9 of the third conductive layer M3 may be less than the thickness T8 of the first conductive layer M1. Therefore, the conductive layer CL in the second portion P2 may further be determined to be the first conductive layer M1 or the third conductive layer M3 through the following way. In detail, in a cross-sectional view of the circuit structure CS, it can be observed that a conductive layer CL with a greater thickness and at least another conductive layer CL adjacent to the conductive layer CL, at least partially overlapped with the conductive layer CL and having a lower thickness are included in the second portion P2. In such condition, the conductive layer CL may be the signal related layer, and the at least another conductive layer CL may be the shielding layer, but not limited thereto. It should be noted that “the thickness of the signal related layer is greater than the thickness of the shielding layer” mentioned above may include the condition that the thickness of at least one signal related layer is greater than the thickness of the shielding layer. In addition, in the structure shown in FIG. 2, when the conductive layer MA serves as the shielding layer (for example, the shielding layer of the first conductive layer M1), the thickness design of the conductive layer MA may refer to the thickness design of the first conductive pad CP1 (that is, greater than or equal to 7 μm) mentioned above instead of the thickness design of the shielding layer mentioned above.

According to the present embodiment, the thickness of a signal related layer in the second portion P2 may be greater than the thickness of a non-signal related layer in the first portion P1. For example, as shown in FIG. 2, the fourth conductive layer M4 in the first portion P1 may have a thickness T10, and the thickness T8 of the first conductive layer M1 may be greater than the thickness T10 of the fourth conductive layer M4. It should be noted that “the thickness of the signal related layer in the second portion P2 is greater than the thickness of the non-signal related layer in the first portion P1” described herein may include the condition that the thickness of at least one signal related layer in the second portion P2 is greater than the thickness of the non-signal related layer in the first portion P1. In addition, although it is not shown in the figure, in the second portion P2, the thickness of the signal related layer (such as the thickness T8) may be greater than the thicknesses of the non-signal related layers (if any) such as the power layer, the ground layer, and the like.

According to the present embodiment, the thickness of the signal related layer in the second portion P2 may be greater than the thickness of the signal related layer in the first portion P1. Specifically, the thickness of at least one signal related layer in the second portion P2 may be greater than the thickness of the signal related layer in the first portion P1. For example, as shown in FIG. 2, the signal related layer (such as the second conductive layer M2) in the first portion P1 may have a thickness T11, and the thickness T8 of the first conductive layer M1 may be greater than the thickness T11 of the second conductive layer M2.

In the present embodiment, the thickness of the conductive layer CL (if any) in the second portion P2 as a non-signal related layer (such as the power layer, the ground layer, and the like), the thickness (such as the thickness T9) of the shielding layer (such as the third conductive layer M3) in the second portion P2, the thickness (such as the thickness T10) of the non-signal related layer (such as the fourth conductive layer M4) in the first portion P1 and the thickness (such as the thickness T11) of the signal related layer (such as the second conductive layer M2) in the first portion P1 may be the same, but not limited thereto. In some embodiments, the thickness (such as the thickness T11) of the signal related layer in the first portion P1 may be greater than the thickness T9 and the thickness T10 and may be less than the thickness T8.

According to the present embodiment, “the first portion P1” mentioned above may be the low signal related portion in the circuit structure CS, and “the second portion P2” mentioned above may be the high signal related portion in the circuit structure CS. Specifically, in the circuit structure CS, the proportion of the conductive layers CL in the first portion P1 as the signal related layers may be less than the proportion of the conductive layers CL in the second portion P2 as the signal related layers. For example, the ratio of the area (such as the top view area) of the conductive layers CL as the signal related layer in the first portion P1 to the area of all the conductive layers CL in the first portion P1 may be defined as a first ratio, and the ratio of the area of the conductive layers CL as the signal related layer in the second portion P2 to the area of all the conductive layers CL in the second portion P2 may be defined as a second ratio, wherein the first ratio is less than the second ratio, but not limited thereto. It should be noted that the first ratio and the second ratio mentioned above may be defined through other suitable ways (for example, the first ratio and the second ratio may be defined by the proportion of the number of conductive layers CL as the signal related layers), which are not limited to be defined through the above-mentioned way. Specifically, in a portion of the circuit structure CS, when the proportion of the conductive layers CL as the signal related layers in the conductive layers CL included in the portion of the circuit structure CS is greater than a specific value (the value may for example be defined according to the demand of design of the electronic device ED), the portion of the circuit structure CS may be regarded as the second portion P2 mentioned above, and the structures and the sizes of the conductive layers CL and the dielectric layers DI in the portion of the circuit structure CS may refer to the structural designs and size designs of the conductive layers CL and the dielectric layers DI in the second portion P2 mentioned above. In the circuit structure CS, the portion(s) other than the second portion(s) P2 may be regarded as the first portion(s) P1, and the structures and the sizes of the conductive layers CL and the dielectric layers DI therein may refer to the structural designs and size designs of the conductive layers CL and the dielectric layers DI in the first portion P1 mentioned above. Through the above-mentioned structural design, when the circuit structure CS is used in high-speed/high-frequency transmission of signals of the first electronic unit EU1, the signal loss of the first electronic unit EU1 may be reduced, thereby improving the electrical performance of the electronic device ED. In addition, in the present embodiment, the structure of the circuit structure CS may be designed such that the second portion P2 may be closer to the first electronic unit EU1 than the first portion P1. Therefore, the signal transmission capability of the circuit structure CS in a high-speed/high-frequency environment may further be improved, or the signal loss of the first electronic unit EU1 during the transmission process may further reduce. It should be noted that in some embodiments, the circuit structure CS may define a plurality of first portions P1 and a plurality of second portions P2 according to the structure of the circuit structure CS. In such condition, the stacking order of the first portions P1 and the second portions P2 may be determined according to the design of the circuit structure CS. In addition, the second portions P2 may have a tendency to be closer to the first electronic unit EU1 than the first portions PI.

It should be noted that the circuit structure CS shown in FIG. 2 is exemplary, and it is not limited in the present embodiment. In other embodiments, the circuit structure CS may further include other suitable elements or layers. Other embodiments of the present disclosure will be described in the following. In order to simplify the description, the same elements or layers in the following embodiments would be labeled with the same symbol, and the features thereof will not be redundantly described. The differences between the embodiments will be detailed in the following.

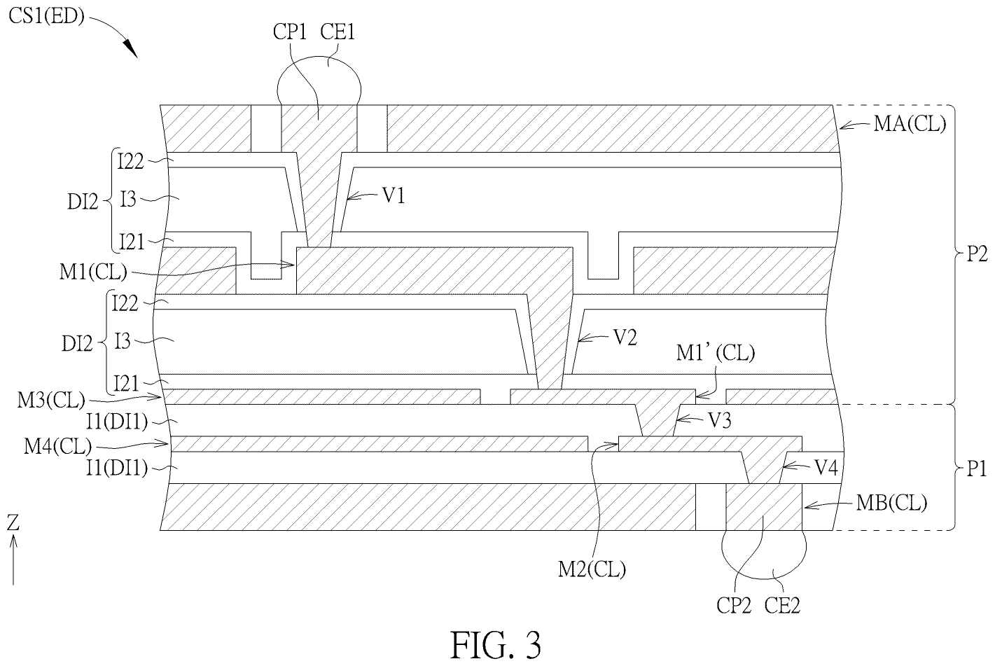

Referring to FIG. 3, FIG. 3 schematically illustrates a cross-sectional view of a circuit structure according to a second embodiment of the present disclosure. One of the main differences between the circuit structure CS1 of the present embodiment and the circuit structure CS shown in FIG. 2 is the disposition way of the second insulating layer. Specifically, as shown in FIG. 3, in the second dielectric layer DI2 of the second portion P2 of the circuit structure CS1, the second insulating layer I22 located on the third insulating layer I3 may extend into the via of the third insulating layer I3 (or the via of the second dielectric layer DI2, such as the via V1 and the via V2), or the second insulating layer I22 may be disposed along the sidewall of the via. In such condition, the second insulating layer I21 and the second insulating layer I22 respectively disposed at two sides of the third insulating layer I3 may contact each other and surround the third insulating layer I3 therebetween. Therefore, the conductive layer CL in the second portion P2 may not contact the third insulating layer I3. Specifically, the conductive layer CL and the third insulating layer I3 may be separated from each other through the second insulating layer I21 and the second insulating layer I22. The features described in the present embodiment may be applied to the embodiments of the present disclosure.

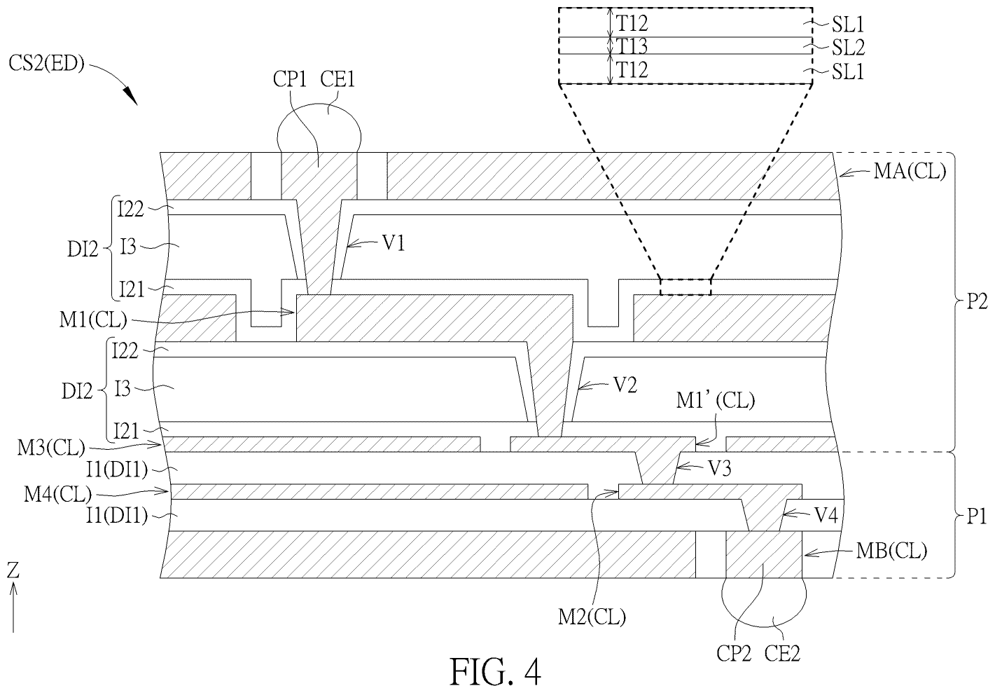

Referring to FIG. 4, FIG. 4 schematically illustrates a cross-sectional view of a circuit structure according to a third embodiment of the present disclosure. One of the differences between the circuit structure CS2 of the present embodiment and the circuit structure CS shown in FIG. 2 is the structure of the second insulating layer. Specifically, in the circuit structure CS2 of the present embodiment, the second insulating layer of the second dielectric layer DI2 in the second portion P2 may include a multi-layer structure. In detail, as shown in FIG. 4, the second insulating layer I21 of the second dielectric layer DI2 may include a first sub layer SL1, a second sub layer SL2 disposed on the first sub layer SL1, and another first sub layer SL1 disposed on the second sub layer SL2, but not limited thereto. In other words, the two first sub layers SL1 are respectively disposed at two sides of the second sub layer SL2, or the second sub layer SL2 is sandwiched between the two first sub layers SL1. In the present embodiment, the first sub layer SL1 may have a thickness T12, and the second sub layer SL2 may have a thickness T13, wherein the thickness T12 of the first sub layer SL1 may be greater than the thickness T13 of the second sub layer SL2. In addition, the oxygen content of the second sub layer SL2 may be less than the oxygen content of the first sub layer SL1, or in other words, the oxygen content of the material of the second sub layer SL2 is less than the oxygen content of the material of the first sub layer SL1. For example, in the present embodiment, the first sub layer SL1 may include silicon oxide, and the second sub layer SL2 may include silicon nitride, but not limited thereto. In some embodiments, the second insulating layer I21 may just include one first sub layer SL1 and one second sub layer SL2, wherein the second sub layer SL2 is disposed on the first sub layer SL1. It should be noted that although it is not shown in the figure, the second insulating layer I22 may also include the above-mentioned multi-layer structure. In addition, the second insulating layer I22 may fill or not fill the via V1 and the via V2, which is not limited to what is shown in FIG. 4. The features of the present embodiment may be applied to the embodiments of the present disclosure.

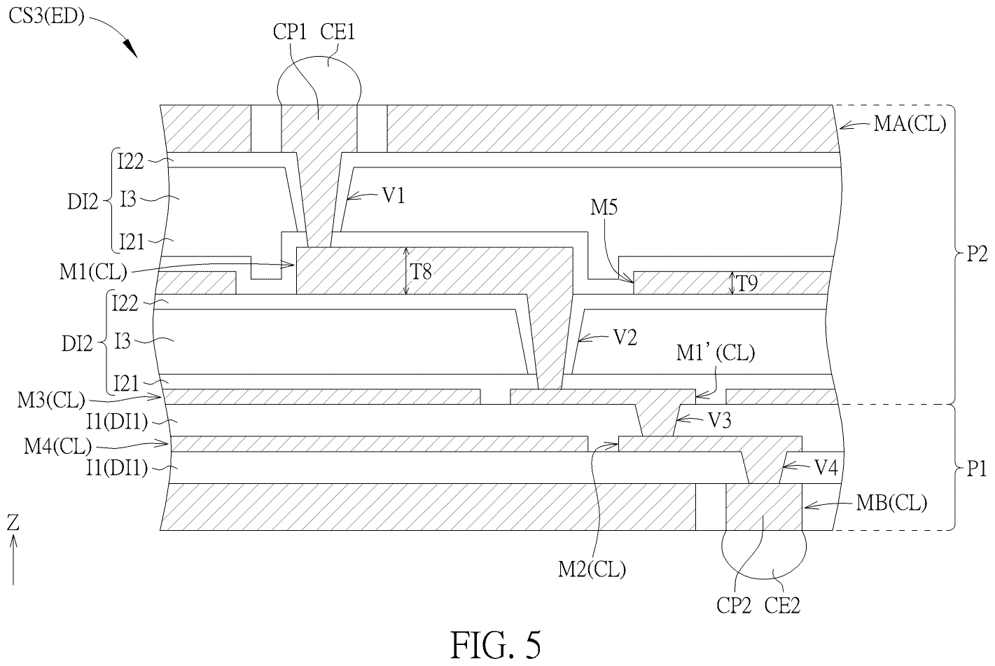

Referring to FIG. 5, FIG. 5 schematically illustrates a cross-sectional view of a circuit structure according to a fourth embodiment of the present disclosure. One of the main differences between the circuit structure CS3 of the present embodiment and the circuit structure CS shown in FIG. 2 is the thickness design of the conductive layer CL of the second portion P2. Returning to FIG. 2, in the second portion P2 of the circuit structure CS, the conductive layers CL at the same layer may have the same thickness. “The conductive layers CL at the same layer” described herein may represent that these conductive layers CL are disposed between the same two adjacent second dielectric layers DI2. For example, as shown in FIG. 2, the conductive layers CL at the same layer as the first conductive layer M1 may have the thickness T8, and the conductive layers CL at the same layer as the third conductive layer M3 may have the thickness T9. It should be noted that in the second portion P2 of the circuit structure CS shown in FIG. 2, the conductive layers at the same layer may be different types of conductive layers or conductive layers of different uses. For example, in FIG. 2, the third conductive layer M3 and the first conductive layer M1′ at the same layer may respectively serve as the shielding layer and the signal related layer. In addition, although it is not shown in FIG. 2, other conductive layers CL at the same layer as the first conductive layer M1 may be signal related layers, shielding layers, power layers, ground layers or other suitable layers.

In another aspect, returning to FIG. 5, in the second portion P2 of the circuit structure CS3 of the present embodiment, the conductive layers CL at the same layer may have different thicknesses. Specifically, in the second portion P2 of the circuit structure CS3, the conductive layers CL at the same layer may respectively be the signal related layers or the shielding layers mentioned above, and thus may have different thicknesses. For example, as shown in FIG. 5, the second portion P2 of the circuit structure CS3 may include the first conductive layer M1 and the conductive layer M5 at the same layer, wherein the first conductive layer M1 may be the signal related layer, and the conductive layer M5 may be the shielding layer, such as the shielding layer of an adjacent signal related layer (not shown). In such condition, the first conductive layer M1 may have the thickness T8, and the conductive layer M5 may have the thickness of the shielding layer mentioned above, that is, the thickness T9, wherein the thickness T8 and the thickness T9 may be different. For example, the thickness T8 may be greater than the thickness T9. It should be noted that the second insulating layer I22 may fill or not fill the via V1 and the via V2, which is not limited to what is shown I FIG. 5. The features of the present embodiment may be applied to the embodiments of the present disclosure.

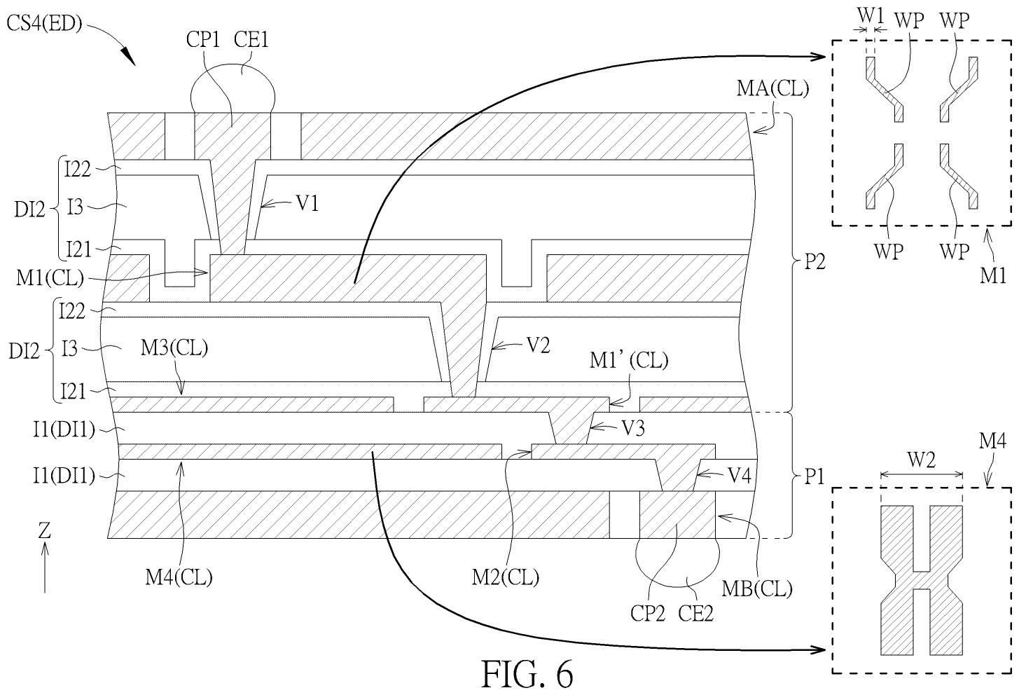

Referring to FIG. 6, FIG. 6 schematically illustrates a circuit structure according to a fifth embodiment of the present disclosure. FIG. 6 shows top view patterns of the fourth conductive layer M4 in the first portion P1 and the first conductive layer M1 in the second portion P2 of the circuit structure CS4. As mentioned above, the fourth conductive layer M4 may be the power layer, the ground layer or other non-signal related layers, and the first conductive layer M1 may be a signal related layer. In other words, the top view pattern of the fourth conductive layer M4 in FIG. 6 may be applied to the top view pattern of non-signal related layers such as the power layer, the ground layer, and the like in the circuit structure CS4, and the top view pattern of the first conductive layer M1 may be applied to the top view pattern of the signal related layers in the circuit structure CS4. As shown in FIG. 6, the top view pattern of the first conductive layer M1 may include a plurality of wire patterns WP, wherein the wire patterns WP may respectively be connected to other conductive layers CL in the circuit structure CS4 to transmit signals, and the top view pattern of the fourth conductive layer M4 may include a continuous solid pattern, but not limited thereto. It should be noted that the top view patterns shown in FIG. 6 are exemplary, and the present embodiment is not limited thereto. According to the present embodiment, the size of the top view pattern of the signal related layer may be less than the size of the top view pattern of the non-signal related layer such as the power layer, the ground layer, and the like. “The size of the top view pattern” described herein may represent the width, the area or other dimensional features of the top view pattern. In some embodiments, as shown in FIG. 6, the top view pattern of the first conductive layer M1 may have the width W1, and the top view pattern of the fourth conductive layer M4 may have the width W2, wherein the width W1 may be less than the width W2. The width W1 may for example be defined as the maximum width of a wire pattern WP in the top view pattern of the first conductive layer M1, and the width W2 may for example be defined as the maximum width of the top view pattern of the fourth conductive layer M4, but not limited thereto. In some embodiments, although it is not shown in FIG. 6, the area of the top view pattern of the first conductive layer M1 may be less than the area of the top view pattern of the fourth conductive layer M4. The area of the top view pattern of the first conductive layer M1 may for example be the sum of the areas of the wire patterns WP in the top view pattern of the first conductive layer M1. The features of the present embodiment may be applied to the embodiments of the present disclosure.

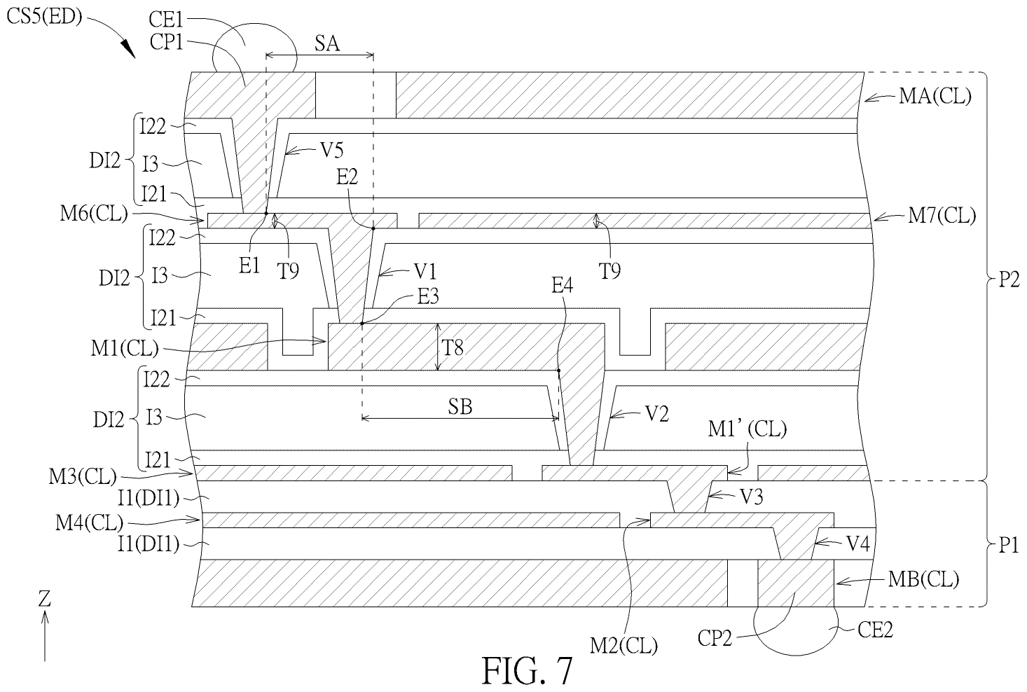

Referring to FIG. 7, FIG. 7 schematically illustrates a cross-sectional view of a circuit structure according to a sixth embodiment of the present disclosure. Compared with the circuit structure CS shown in FIG. 2, the second portion P2 of the circuit structure CS5 of the present embodiment may not include the signal related layer adjacent to the conductive layer MA and at least partially overlapped with the conductive layer MA, and therefore, the conductive layer MA may not serve as the shielding layer. For example, as shown in FIG. 7, the circuit structure CS5 may further include a conductive layer M6 and a conductive layer M7 disposed between the conductive layer MA and the first conductive layer M1. The conductive layer M6 may be the signal related layer, wherein the first conductive layer M1 may be electrically connected to the first conductive pad CP1 through the conductive layer M6. The conductive layer M7 may be adjacent to the first conductive layer M1 and at least partially overlapped with the first conductive layer M1, and therefore, the conductive layer M7 may serve as the shielding layer of the first conductive layer M1.

In the present embodiment, the conductive layer M6 and the conductive layer M7 at the same layer may have the same thickness to simplify the manufacturing process of the circuit structure CS5. FIG. 2 also shows that the conductive layers CL at the same layer have the same thickness. Specifically, the thickness of the conductive layer M6 and the thickness of the conductive layer M7 may be the thickness of the shielding layer shown in FIG. 2, that is, the thickness T9 of the third conductive layer M3. That is, the thickness of the conductive layer M6 as a signal related layer may be less than the thickness T8 of the first conductive layer M1 as another signal related layer. In such condition, the length of the transmission path of the signal of the first electronic unit EU1 in the conductive layer M6 may be shorter than the length of the transmission path of the signal of the first electronic unit EU1 in the first conductive layer M1. In the present embodiment, the length of the transmission path of signal in a signal related layer may be the distance between the two vias corresponding to the signal related layer. Specifically, the second dielectric layer DI2 disposed between the conductive layer MA and the conductive layer M6 in the circuit structure CS5 may include a via V5, such that the first conductive pad CP1 may be electrically connected to the conductive layer M6 through the via V5. In addition, the conductive layer M6 may be electrically connected to the first conductive layer M1 through the via V1. Therefore, the via V5 and the via V1 may be considered to correspond to the conductive layer M6. The conductive layer M1 may be electrically connected to the first conductive layer M1′ through the via V2. Therefore, the via V1 and the via V2 may be considered to correspond to the first conductive layer M1. In such condition, the length of the transmission path SA of the signal of the first electronic unit EU1 in the conductive layer M6 may be the distance between the via V1 and the via V5 that correspond to the conductive layer M6. For example, the length of the transmission path SA may be defined as the distance between an edge E1 of the via V5 in contact with the conductive layer M6 and adjacent to the via V1 and an edge E2 of the via V1 in contact with the conductive layer M6 and adjacent to the via V5 in a direction perpendicular to the normal direction of the electronic device ED. The length of the transmission path SB of the signal of the first electronic unit EU1 in the first conductive layer M1 may be the distance between the via V1 and the via V2 that correspond to the first conductive layer M1. For example, the length of the transmission path SB may be defined as the distance between an edge E3 of the via V1 in contact with the first conductive layer M1 and adjacent to the via V2 and an edge E4 of the via V2 in contact with the first conductive layer M1 and adjacent to the via V1 in a direction perpendicular to the normal direction of the electronic device ED. In the present embodiment, the length of the transmission path SB may be greater than the length of the transmission path SA. Specifically, in the present embodiment, when the length of the transmission path of the signal of the first electronic unit EU1 in a signal related layer is shorter, the signal related layer and the shielding layer, the ground layer or other non-signal related layers at the same layer as the signal related layer may be designed to have the thickness T9 of the shielding layer (such as the third conductive layer M3) mentioned above; and when the length of the transmission path of the signal of the first electronic unit EU1 in a signal related layer is longer, the signal related layer and the shielding layer, the ground layer or other non-signal related layers at the same layer as the signal related layer may be designed to have the thickness T8 of the signal related layer (such as the first conductive layer M1) mentioned above, but not limited thereto. Or, for the conductive layers CL at the same layer, when the proportion of the signal related layer(s) is small, the signal related layer(s) may be designed to have the thickness of the shielding layer mentioned above, that is, the thickness T9; and when the proportion of the signal related layer (s) is large, the signal related layer(s) may be designed to have the thickness of the signal related layer mentioned above, that is, the thickness T8. For example, in FIG. 7, the thickness of the first conductive layer M1′ may be the same as the thickness T9 of the shielding layer, but not limited thereto. Similarly, the thickness of the first conductive layer M1′ shown in FIG. 2 may be the same as the thickness T9 of the shielding layer. Through the above-mentioned design, the signal loss of the first electronic unit EU1 during transmission may be reduced while simplifying the manufacturing process of the circuit structure CS5. It should be noted that in some embodiments, the thickness of the conductive layer M6 as the signal related layer may be increased, such that the thickness of the conductive layer M6 may be greater than the thickness of the conductive layer M7. For example, the thickness of the conductive layer M6 may be greater than the thickness T9 of the conductive layer M7 and less than or equal to the thickness T8 of the first conductive layer M1. The features of the present embodiment may be applied to the embodiments of the present disclosure.

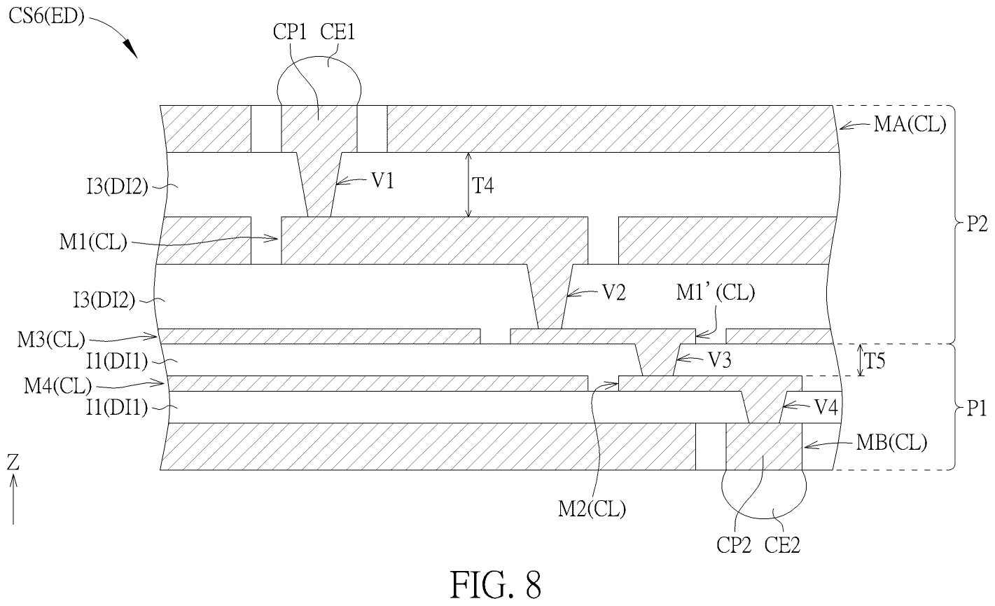

Referring to FIG. 8, FIG. 8 schematically illustrates a cross-sectional view of a circuit structure according to a seventh embodiment of the present disclosure. According to the present embodiment, the second dielectric layer DI2 in the second portion P2 of the circuit structure CS6 may only include the third insulating layer I3 but not include the second insulating layer. In other words, the second dielectric layer DI2 may be defined by the third insulating layer I3, that is, the second dielectric layer DI2 may include a single-layer structure. In such condition, the thickness T4 of the second dielectric layer DI2 mentioned above may be the thickness of the third insulating layer I3, which may be greater than the thickness T5 of the first dielectric layer DI1 (or the first insulating layer I1). That is, the thickness T4 of the third insulating layer I3 may be greater than the thickness T5 of the first insulating layer I1. In addition, the dielectric loss (or dissipation factor (Df)) of the third insulating layer I3 may be less than the dielectric loss of the first insulating layer I1, such that the dielectric loss of the second dielectric layer DI2 is less than the dielectric loss of the first dielectric layer DI1. Specifically, the material of the third insulating layer I3 and the material of the first insulating layer I1 may be different, wherein the dielectric loss of the material of the third insulating layer I3 is less than the dielectric loss of the material of the first insulating layer I1.

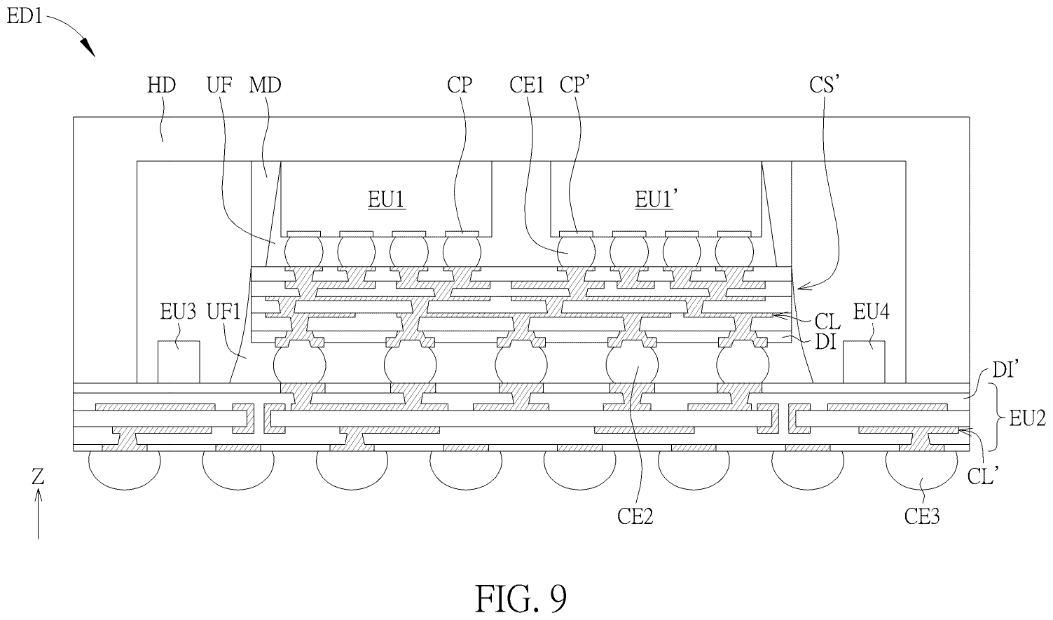

Referring to FIG. 9, FIG. 9 schematically illustrates a cross-sectional view of an electronic device according to an eighth embodiment of the present disclosure. According to the present embodiment, the electronic device ED1 may include a circuit structure CS′, a first electronic unit EU1, a first electronic unit EU1′, an underfill layer UF and a molding layer MD, but not limited thereto. The circuit structure CS' may be formed by stacking at least one conductive layer CL and at least one dielectric layer DI. It should be noted that the circuit structure CS' shown in FIG. 9 is exemplary, and the circuit structure CS' of the present embodiment may refer to the circuit structure in any embodiment mentioned above. The circuit structure CS' may be electrically connected to the first electronic unit EU1 and the first electronic unit EU1′ (for example, being electrically connected to the conductive pads CP of the first electronic unit EU1 and the conductive pads CP′ of the first electronic unit EU1′) through the first connecting element CE1. The underfill layer UF may surround the first connecting element CE1. The underfill layer UF may further surround the first electronic unit EU1 and the first electronic unit EU1′, but not limited thereto. The molding layer MD may surround the first electronic unit EU1, the first electronic unit EU1′ and/or the underfill layer UF. The detail of the above-mentioned structure may refer to FIG. 1 and related contents mentioned above, and will not be redundantly described. Compared to the electronic device ED shown in FIG. 1, the molding layer MD of the electronic device ED1 of the present embodiment may surround a plurality of electronic units (for example, two electronic units), and the circuit structure CS' may be electrically connected to these electronic units.

According to the present embodiment, the electronic device ED1 may further include a second electronic unit EU2 disposed at a side of the circuit structure CS' opposite to the first electronic unit EU1 and the first electronic unit EU1′. The circuit structure CS' may be electrically connected to the second electronic unit EU2. Specifically, the second electronic unit EU2 may include a structure formed by stacking at least one conductive layer CL′ and at least one dielectric layer DI′, and the circuit structure CS' may be electrically connected to the conductive layers CL′ in the second electronic unit EU2 through the second connecting element CE2 mentioned above, thereby being electrically connected to the second electronic unit EU2. The second electronic unit EU2 may for example include a circuit board, but not limited thereto. In such condition, the electronic device ED1 may further include a third electronic unit EU3 and a fourth electronic unit EU4 disposed on the second electronic unit EU2 (that is, on the circuit board). Although it is not shown in the figure, the third electronic unit EU3 and the fourth electronic unit EU4 may be electrically connected to the second electronic unit EU2, for example, the third electronic unit EU3 and the fourth electronic unit EU4 may be bonded on the second electronic unit EU2. The electronic device ED1 may further include a third connecting element CE3 disposed at a side of the second electronic unit EU2 opposite to the circuit structure CS′. The third connecting element CE3 may be electrically connected to the second electronic unit EU2 (for example, the conductive layers CL′ in the second electronic unit EU2). Therefore, the first electronic unit EU1, the first electronic unit EU1′, the third electronic unit EU3 and the fourth electronic unit EU4 may be electrically connected to other electronic units (not shown) through the second electronic unit EU2 and the third connecting element CE3.

In some embodiments, the electronic device ED1 may further include a heat dissipation layer HD. As shown in FIG. 9, the heat dissipation layer HD may have a cover-shaped structure and be disposed on the second electronic unit EU2 to cover the elements such as the circuit structure CS′, the first electronic unit EU1, the first electronic unit EU1′, the third electronic unit EU3 and the fourth electronic unit EU4. The heat dissipation layer HD may contact the surface of the first electronic unit EU1 and the surface of the first electronic unit EU1′ (for example, the surfaces opposite to the circuit structure CS′), but not limited thereto.

It should be note that the structure of the electronic device ED1 is not limited to what is shown in FIG. 9 and may further include other suitable elements or layers.

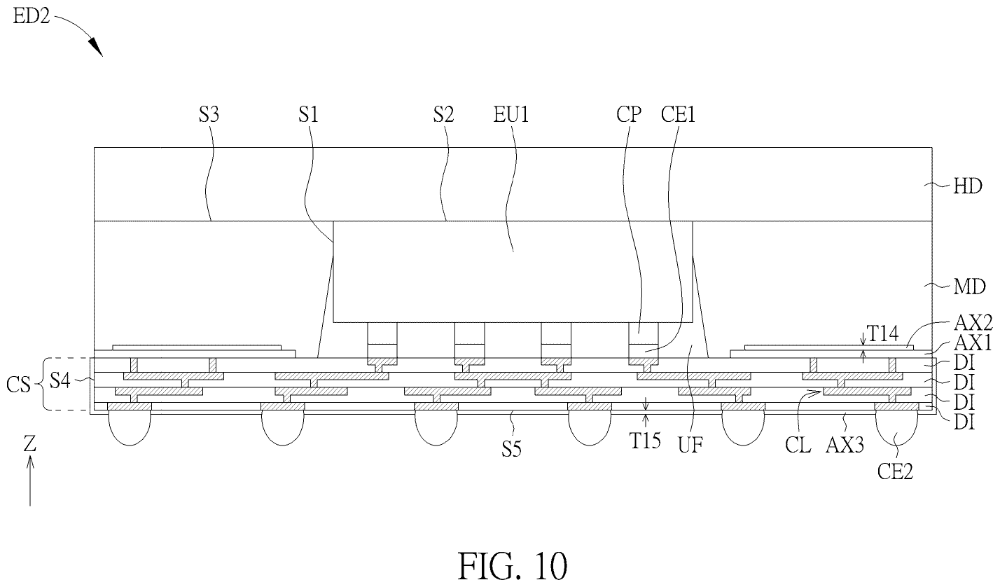

Referring to FIG. 10, FIG. 10 schematically illustrates a cross-sectional view of an electronic device according to a ninth embodiment of the present disclosure. Compared with the electronic device ED1 shown in FIG. 1, the electronic device ED2 of the present embodiment may further include a second auxiliary layer AX2, wherein the second auxiliary layer AX2 may be disposed between the molding layer MD and the first auxiliary layer AX1. Through the disposition of the second auxiliary layer AX2, the adhesion between the molding layer MD and the first auxiliary layer AX1 may be improved. In addition, the electronic device ED2 may further include a third auxiliary layer AX3, wherein the third auxiliary layer AX3 may cover the side surface S4 of the circuit structure CS and the surface S5 (that is, the bottom surface) of the circuit structure CS opposite to the molding layer MD. Specifically, the third auxiliary layer AX3 may cover the circuit structure CS, such that the circuit structure CS may not be exposed to external environment. The third auxiliary layer AX3 may provide the moisture and oxygen blocking effect for the circuit structure CS. The second auxiliary layer AX2 and the third auxiliary layer AX3 may include any suitable organic insulating material or inorganic insulating material, wherein the organic insulating material may include benzocyclobutene (BCB), polymers, resins or other suitable materials, and the inorganic insulating material may include silicon oxide, silicon nitride, silicon oxynitride (SiOₓN_{y}), but not limited thereto. Moreover, in the present embodiment, the second auxiliary layer AX2 may have a thickness T14, and the third auxiliary layer AX3 may have a thickness T15, wherein the thickness T14 and the thickness T15 may be less than the thickness of the first dielectric layer DI1 (that is, the first insulating layer I1) of the first portion P1 of the circuit structure CS, that is, the thickness T5 mentioned above.

In summary, an electronic device is provided by the present disclosure, wherein the electronic device includes an electronic unit and a circuit structure electrically connected to the electronic unit. The circuit structure may be divided into at least one first portion and at least one second portion according to the disposition way of the signal related layers, wherein the first portion and the second portion may have different structural designs of conductive layers and insulating layers. Therefore, when the signals of the electronic unit are transmitted through the circuit structure, the signal transmission capability of the circuit structure in a high-speed/high-frequency environment may be improved, or the signal loss of the electronic unit during the transmission process may reduce.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
at least one first electronic unit;
a molding layer surrounding the at least one first electronic unit; and
a circuit structure disposed at a side of the molding layer and electrically connected to the at least one first electronic unit, wherein the circuit structure comprises a first portion and a second portion, and in a normal direction of the electronic device, the second portion is disposed between the first portion and the at least one first electronic unit;
wherein the first portion comprises a first insulating layer, the second portion comprises a second insulating layer and a third insulating layer, the second insulating layer is disposed between the first insulating layer and the third insulating layer, the third insulating layer is disposed between the second insulating layer and the molding layer, and a dielectric loss of the second insulating layer is less than a dielectric loss of the first insulating layer and a dielectric loss of the third insulating layer.

2. The electronic device of claim 1, wherein the first insulating layer defines a first dielectric layer of the first portion, the second insulating layer and the third insulating layer define a second dielectric layer of the second portion, and a thickness of the first dielectric layer is less than a thickness of the second dielectric layer.

3. The electronic device of claim 1, wherein a ratio of a thickness of the second insulating layer to a thickness of the third insulating layer is greater than or equal to 0.005 and less than or equal to 0.5.

4. The electronic device of claim 1, wherein the circuit structure further comprises a first conductive pad and a second conductive pad respectively be disposed at two sides of the circuit structure, the first conductive pad is disposed between the second conductive pad and the at least one first electronic unit, and a thickness of the second conductive pad is greater than a thickness of the first conductive pad.

5. The electronic device of claim 4, wherein the thickness of the first conductive pad and the thickness of the second conductive pad are greater than or equal to 7 micrometers.

6. The electronic device of claim 4, further comprising:
a first connecting element overlapped with the first conductive pad; and
a second connecting element overlapped with the second conductive pad;
wherein an elastic coefficient of the first connecting element is different from an elastic coefficient of the second connecting element.

7. The electronic device of claim 6, further comprising at least one second electronic unit disposed at a side of the circuit structure opposite to the at least one first electronic unit, wherein the circuit structure is electrically connected to the at least one first electronic unit through the first connecting element, and the circuit structure is electrically connected to the at least one second electronic unit through the second connecting element.

8. The electronic device of claim 1, wherein the second portion of the circuit structure further comprises another second insulating layer disposed on the third insulating layer, and the third insulating layer is sandwiched between the second insulating layer and the another second insulating layer.

9. The electronic device of claim 8, wherein a coefficient of thermal expansion of the second insulating layer and a coefficient of thermal expansion of the another second insulating layer are less than a coefficient of thermal expansion of the third insulating layer.

10. The electronic device of claim 8, wherein the third insulating layer comprises a via, and the another second insulating layer extends into the via.

11. The electronic device of claim 1, wherein the second insulating layer comprises a first sub layer and a second sub layer disposed on the first sub layer, and a thickness of the first sub layer is greater than a thickness of the second sub layer.

12. The electronic device of claim 11, wherein an oxygen content of the second sub layer is less than an oxygen content of the first sub layer.

13. The electronic device of claim 11, wherein the second insulating layer further comprises another first sub layer disposed on the second sub layer.

14. The electronic device of claim 1, further comprising a first auxiliary layer disposed between the molding layer and the circuit structure.

15. The electronic device of claim 14, further comprising a second auxiliary layer disposed between the molding layer and the first auxiliary layer.

16. The electronic device of claim 15, further comprising a third auxiliary layer, wherein the third auxiliary layer covers a side surface of the circuit structure and a surface of the circuit structure opposite to the molding layer.

17. The electronic device of claim 16, wherein a thickness of the second auxiliary layer and a thickness of the third auxiliary layer are less than a thickness of the first insulating layer of the first portion.

18. The electronic device of claim 1, wherein a material of the second insulating layer comprises silicon nitride or silicon oxide.

19. The electronic device of claim 1, wherein the second portion of the circuit structure comprises a first conductive layer, the first conductive layer is electrically connected to the at least one first electronic unit, and a thickness of the first conductive layer is greater than or equal to 3 micrometers.

20. The electronic device of claim 19, wherein the second portion of the circuit structure further comprises a second conductive layer adjacent to the first conductive layer, the second conductive layer at least partially overlaps the first conductive layer in the normal direction of the electronic device, and a thickness of the second conductive layer is less than the thickness of the first conductive layer.
